(19) United States
(12) Patent Application Publication
(10) Pub. No.: US 2014/0318600 A1
(43) Pub. Date: Oct. 30, 2014

(54) CONCENTRATING PHOTOVOLTAIC COLLECTOR

(71) Applicants: James P. Walsh, Boulder, CO (US); Peter John Novak, Longmont, CO (US); Robert Fenwick-Smith, Boulder, CO (US); William Ross McCluney, Cape Canaveral, FL (US)

(72) Inventors: James P. Walsh, Boulder, CO (US); Peter John Novak, Longmont, CO (US); Robert Fenwick-Smith, Boulder, CO (US); William Ross McCluney, Cape Canaveral, FL (US)

(73) Assignee: Sunflower Corporation, Boulder, CO (US)

(21) Appl. No.: 14/358,637

(22) PCT Filed: Nov. 15, 2012
(86) PCT No.: PCT/US2012/065300

§ 371 Date: May 15, 2014

Related U.S. Application Data
(60) Provisional application No. 61/559,968, filed on Nov. 15, 2011.

(51) Int. Cl. H01L 31/052

(52) U.S. Cl. CPC H01L 31/0525
USPC 136/246

(57) ABSTRACT

A combined solar daylighting system and photovoltaic electric generation system operates when daylighting both is and is not required. A photovoltaic (PV) array is mounted on the back side of a secondary reflector of the daylighting system with the secondary reflector hinged in such a way that, when sunlight is not needed, the PV array can be positioned to collect the concentrated solar radiation from the primary reflector and convert it into electrical energy. When sunlight is needed for daylighting, the PV array on the back of the secondary reflector receives unconcentrated solar radiation, thereby converting it to electrical energy, though not in as large a quantity as when receiving concentrated solar radiation from the primary concentrating reflector in solar-only mode.

### CROSS REFERENCE TO RELATED APPLICATIONS

This application claims the benefit of priority pursuant to 35 U.S.C. §119(e) of U.S. provisional application No. 61/559,968 filed 15 Nov. 2011 entitled “Concentrating photovoltaic collector,” which is hereby incorporated herein by reference in its entirety for the purposes of PCT Rule 20.6.

### TECHNICAL FIELD

The technology described herein relates to solar daylighting and photovoltaic electrical generation systems.

### BACKGROUND

Anidolic lighting systems use anidolic or nonimaging optical components (typically parabolic or elliptical mirrors) to capture exterior sunlight and direct it deeply into rooms, while also scattering rays to avoid glare. Anidolic, or non-imaging, mirrors are traditionally used in industrial solar concentrators. Light captured and narrowed by these mirrors in daylighting applications does not converge into a single focal point; the system is unable to form an image of the light source and is thus called non-imaging, or anidolic. Some anidolic, “Mersenne-like” reflector systems use truncated parabolic troughs as primary and secondary reflectors. With troughs, the output beam of radiation is concentrated in only one axis, that is, along the length of the trough as measured along the longitudinal axis. Similar to circularly symmetric dish-type systems, the output beam is collimated, i.e., composed of nominally parallel rays, whenever parallel rays are axially incident on the primary mirror. As such, while inadequate for imaging applications, these reflector systems are, however, adequate for daylighting and solar energy systems.

The information included in this Background section of the specification, including any references cited herein and any description or discussion thereof, is included for technical reference purposes only and is not to be regarded subject matter by which the scope of the invention as defined in the claims is to be bound.

### SUMMARY

The technology disclosed herein relates to the combination of a solar daylighting system and a photovoltaic electric generation system that operates when daylighting both is and is not required. In one exemplary implementation, a photovoltaic (PV) array may be mounted on the back side of a secondary reflector of the daylighting system with the secondary reflector hinged in such a way that, when sunlight is not needed, the PV array can be positioned to collect the concentrated solar radiation from the primary reflector and convert it into electrical energy. When sunlight is needed for daylighting, the PV array on the back of the secondary reflector receives unconcentrated solar radiation, thereby converting it to electrical energy, though not in as large a quantity as when receiving concentrated solar radiation from the primary concentrating reflector in solar-only mode.

In another implementation, when in daylighting mode, most of the concentrated radiation reaching the secondary reflector may be reflected through an aperture in the primary reflector and the resulting concentrated beam of daylight illumination is transmitted to a distribution system within the structure. A modest-sized PV array may be provided about the perimeter of the secondary reflector. A small part of the concentrated radiation outside the perimeter of the secondary reflector may be received by the perimeter PV array, which produces additional electrical energy to add that produced by the PV array on the back side of the secondary reflector.

In a further implementation, a failsafe configuration of the daylighting system is assumed in the absence of a control signal indicating that sunlight is needed. In the failsafe configuration, the PV array is automatically interposed to receive the concentrated light and prevent its specular reflection downward into the space below the primary reflector and electricity will be generated from whatever sunlight is available. In one embodiment, a spring-loaded or gravity-actuated mechanism may force the secondary reflector mount into the PV mode in the absence of electrical power forcing the secondary reflector to be in place for sunlight harvesting or when an electrical signal calling for sunlight is not present. When the PV array is interposed, only a modest portion of the solar radiation falling on it from the primary reflector is reflected back toward the aperture in the primary mirror and what radiation is so reflected is spread laterally and semi-diffusely to greatly reduce the solar radiation passing through the aperture in the primary reflector.

In another exemplary implementation, a solar daylighting apparatus includes a primary reflector, a secondary reflector, a transmission conduit, and a photovoltaic array. The primary reflector may be positioned to receive and reflect incident sunlight. The secondary reflector may be mounted at a position opposite the primary reflector to receive and reflect concentrated light reflected from the primary reflector. The transmission conduit may be configured to receive concentrated light reflected from the secondary reflector and transmit the concentrated light to a distribution apparatus within a building. The photovoltaic array may be movably mounted within the solar daylighting apparatus from a first position of noninterference with the reception of the concentrated light within the transmission conduit to a second position to receive the concentrated light reflected from either the primary reflector or the secondary reflector. When in the second position, the photovoltaic array thereby intercepts the concentrated light and prevents reception of the concentrated light within the transmission conduit.

In a further exemplary implementation, a solar daylighting apparatus includes a primary solar collector and a secondary solar. The primary solar collector concentrates incident light by reflection. The secondary solar collector receives concentrated light from the primary solar collector and shifts from being a reflective concentrator to being a radiant energy collector.

In an alternative exemplary implementation, a method for configuring a solar daylighting system is provided. The solar daylighting system may have a photovoltaic array movably mounted within the system from a first position of noninterference with reception of concentrated light within a transmission conduit to a second position to receive the concentrated light reflected from either a primary reflector or a secondary reflector and thereby intercept the concentrated light and prevent reception of the concentrated light within the transmission conduit. A lacuna may be identified in the concentrated light reflected from the primary reflector resulting from shadowing of the primary reflector by the secondary reflector. A configuration of the photovoltaic array may be adjusted with respect to a focal length of the concentrated light reflected from the primary reflector to minimize the lacuna.

In yet another exemplary implementation, a method for increasing collection of photovoltaic energy in a solar daylighting system having a primary reflector, a secondary reflector, and a transmission conduit is provided. A width of the primary reflector perpendicular to both an optical axis and a longitudinal axis may be increased. A width of a mounting platform for the secondary reflector may be increased an amount equal to the increased width of the primary reflector and in a direction parallel to the increased width of the primary reflector. An area of the mounting platform around the secondary reflector corresponding to the increased width may be populated with photovoltaic solar cells wherein the photovoltaic solar cells receive concentrated solar flux reflected from the increased width of the primary reflector beyond flux needed for illumination of the secondary reflector.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. A more extensive presentation of features, details, utilities, and advantages of the present invention as defined in the claims is provided in the following written description of various embodiments of the invention and illustrated in the accompanying drawings.

### BRIEF DESCRIPTION OF THE DRAWINGS

FIG. 1A is a schematic, perspective view of an exemplary implementation of a daylighting system composed of a Mersenne reflector system composed of a rectangular primary reflector, a convex secondary reflector, a PV array panel on an opposite side of the secondary reflector, and a rotating drive for the secondary reflector.

FIG. 1B is a schematic, top plan view of the daylighting system of FIG. 1A.

FIG. 1C is a schematic, right side elevation view of the daylighting system of FIG. 1A.

FIG. 1D is a schematic, front elevation view of the daylighting system of FIG. 1A with the secondary reflector oriented toward the primary reflector.

FIG. 1E is a schematic, front elevation view of the daylighting system of FIG. 1A with the curved PV array panel oriented toward the primary reflector.

FIG. 2A is a front isometric view of another exemplary implementation of a daylighting system composed of a Mersenne reflector system including a convex primary reflector with an elliptical perimeter, a secondary reflector, a PV array panel on an opposite side of the secondary reflector, and a rotating drive for the secondary reflector.

FIG. 2B is a top isometric view of the daylighting system of FIG. 2A.

FIG. 2C is a front elevation view of the daylighting system of FIG. 2A.

FIG. 2D is a top plan view of the daylighting system of FIG. 2A.

FIG. 2E is a schematic, perspective view of the daylighting system of FIG. 2A depicting the PV array panel oriented toward the primary reflector.

FIG. 2F is a schematic, top plan view of the daylighting system of FIG. 2E.

FIG. 2G is a schematic, right side elevation view of the daylighting system of FIG. 2E.

FIG. 2H is a schematic, front elevation view of the daylighting system of FIG. 2E with the secondary reflector oriented toward the primary reflector.

FIG. 2I is a schematic, front elevation view of the daylighting system of FIG. 2E with the PV array panel oriented toward the primary reflector.

FIG. 3 is a schematic diagram of some optical ray locations exhibiting a lacuna pattern formed in the collimated concentrated flux from an elliptical primary reflector.

FIG. 4A is a schematic, front elevation view of view of an alternate exemplary implementation of a daylighting system including a flat PV panel mounted on an opposite side of and spaced apart from a convex secondary reflector.

FIG. 4B is a schematic, front elevation view of f an exemplary implementation of a daylighting system similar to FIG. 4A, but with the flat PV panel spaced closer to the back side of the secondary reflector in order to increase the focal length from the primary reflector.

FIG. 5 is a schematic, front elevation view of an exemplary implementation of a daylighting system including a concave curved PV panel that is mounted within a concave area on the opposite side of the convex secondary reflector and that receives diminished light concentration due to a lacuna effect.

FIG. 6 is a schematic, front elevation view of an exemplary implementation of a daylighting system similar to FIG. 4 with a split PV panel to better capture light flux and counter a lacuna in the reflection from the primary reflector.

FIG. 7 is a schematic, front elevation view of an exemplary implementation of a daylighting system wherein the primary reflector is truncated in length adjacent a transmission cavity and the halves of the primary reflector are moved toward each other to reduce a lacuna in the reflection from the primary reflector.

FIG. 8 is a schematic, front elevation view of an exemplary implementation of a daylighting system that conceptually illustrates the relationship between the optics of the primary reflector and its focal line with respect to a convex secondary reflector and a convex PV array.

FIG. 9A is a schematic, perspective view of view of an alternate exemplary implementation of a daylighting system including a convex PV panel on an opposite side of a circular secondary reflector with additional PV panels on the corners of a rectangular support structure on which the secondary reflector is mounted and having a secondary reflector with an off-center axis of rotation for a gravity failsafe system.

FIG. 9B is a schematic, top plan view of the daylighting system of FIG. 9A.

FIG. 9C is a schematic, right side elevation view of the daylighting system of FIG. 9A.

FIG. 10A is a schematic top plan view of a version of the exemplary daylighting system of FIGS. 2A-2E with a circular perimeter secondary reflector surrounded by a square perimeter that may house additional PV cells.

FIG. 10B is a schematic top plan view of the system of FIG. 10B, but with the primary reflector widened to a larger perimeter and the support structure for the secondary reflector widened to a larger rectangular perimeter, which may be filled with PV cells to take advantage of the larger area and greater flux of solar radiation.

FIG. 11A is a schematic perspective view of an exemplary daylighting system including a hinged cover with a PV array mounted over the transmission aperture into the building.

FIG. 11B is a schematic front elevation view of the daylighting system of FIG. 11A.

FIG. 12 is a schematic perspective view of an exemplary daylighting system including a sliding cover with a PV array mounted over the transmission aperture into the building.

FIG. 13 is a schematic perspective view of a prior art dish-shaped Mersenne reflector system.

FIG. 14A is a schematic perspective view of a dish-shaped Mersenne reflector system with an extended diameter primary reflector and an extended diameter secondary reflector with a PV array covering the extended portion of the secondary reflector.

FIG. 14B is a schematic perspective view of the secondary reflector of FIG. 14A with the reflective surface directed toward the aperture in the primary reflector.

FIG. 14C is a schematic perspective view of the secondary reflector of FIG. 14A depicting the center portion transitioning from a reflective surface to a surface covered with a PV array.

FIG. 14D is a schematic perspective view of the secondary reflector of FIG. 14A depicting the center portion as a surface covered with a PV array to complement the PV array covering the extended portion.

### DETAILED DESCRIPTION

The present disclosure relates to a concentrated light daylighting system that additionally provides an option for photovoltaic (PV) electrical generation in conjunction with or in lieu of the daylighting function. In one implementation, a photovoltaic (PV) array of concentrating PV cells may be mounted on the back side of the secondary reflector. The secondary reflector may be pivotally mounted in such a way that when sunlight is not needed from the daylighting system, the PV array can collect concentrated solar radiation from the primary reflector and convert it into electrical energy.

The PV system may be utilized when the daylighting system is in a “standby” mode, i.e., when lighting for the building is not required. For example, many warehouses are not regularly occupied by personnel and there is thus no need for constant light. Further, if light is not required, it may be desirable to close off the transmission conduit from the collector array to reduce thermal cooling loss through the transmission conduit and thermal heat gain caused by the heat energy directed by the reflectors. This unused solar energy may be converted into electricity for charging system batteries, for direct energy supply to building needs, for charging batteries to provide electrical services to the building (e.g., general power or nighttime lighting), and/or for providing energy to the grid by directing the collected light to a PV array.

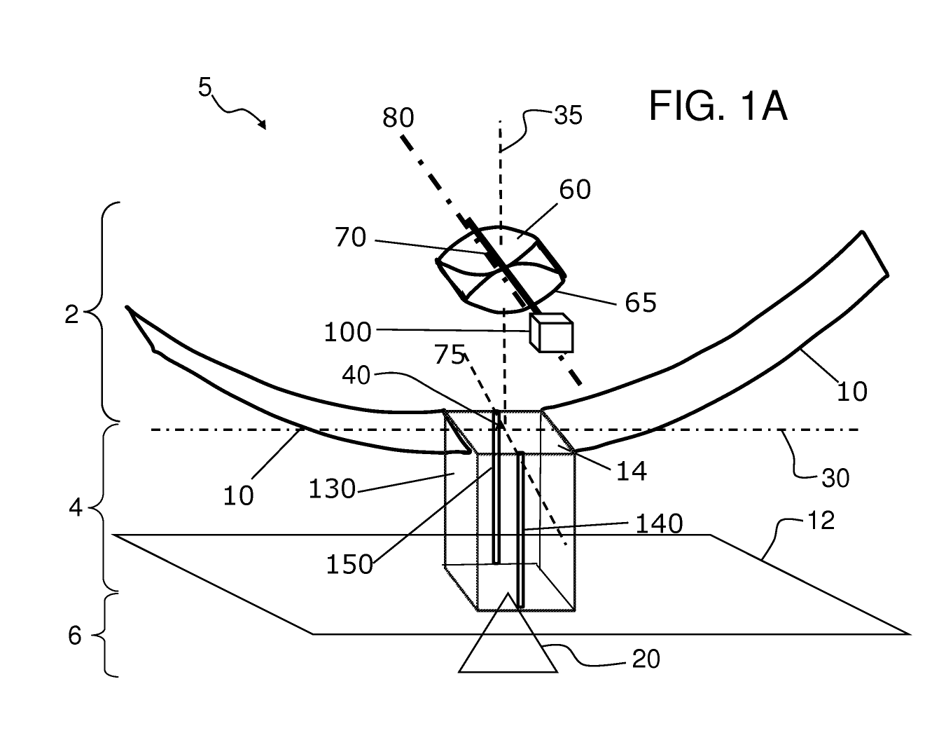

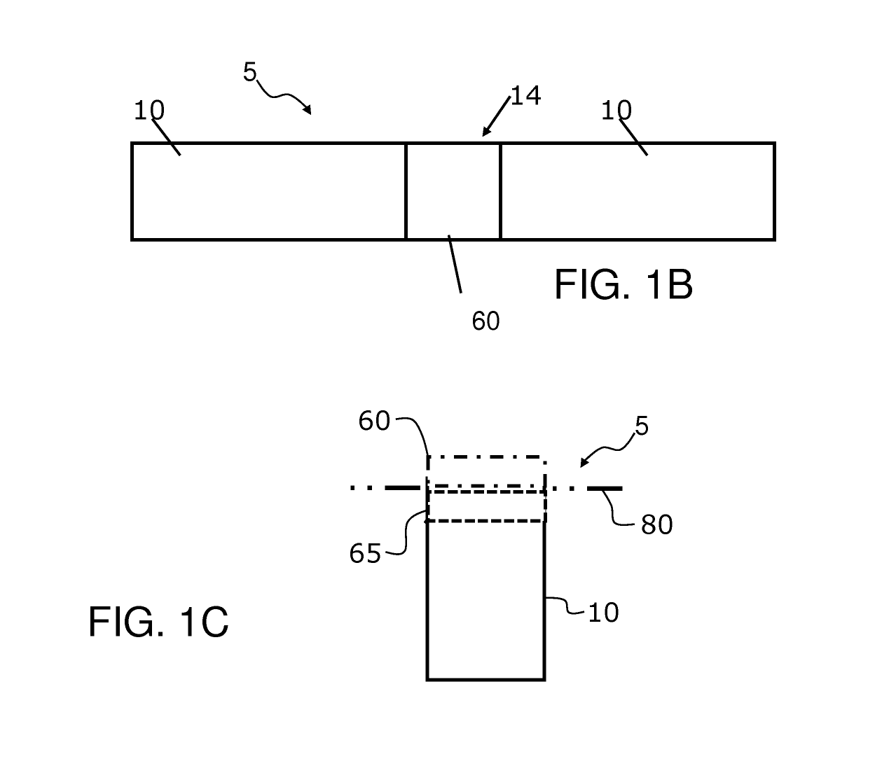

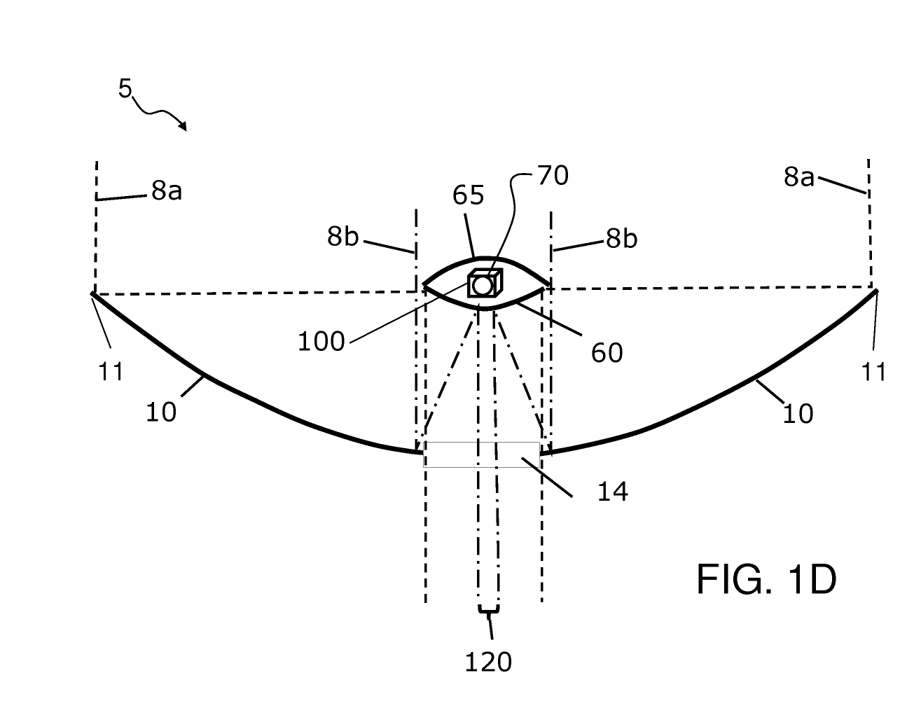

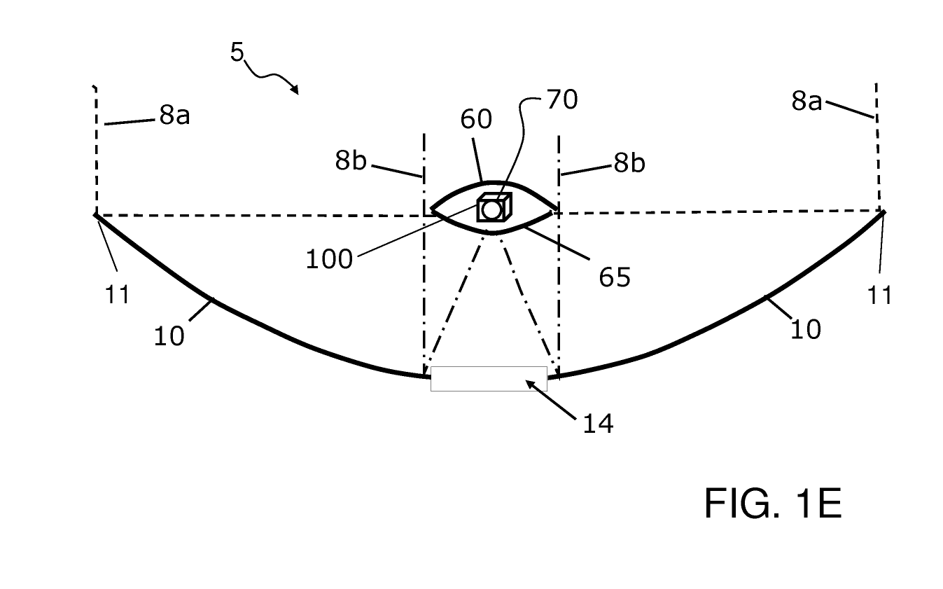

One exemplary implementation of a daylighting system 5 enhanced with a PV array 65 is depicted in FIG. 1A-1E. In this embodiment, the daylighting system 5 may be composed of a harvester portion 2, a transmission portion 4, and a distribution portion 6). The harvester portion 2 may have a primary reflector 10 and a secondary reflector 60 mounted on a sun-tracking, rotating support structure and arranged in a Mersenne configuration. The transmission portion 4 may have a light transmission conduit 130 that extends through an aperture in a support structure, generally the roof of a building, to transmit the collected light via beam-steering optics to a luminaire or other light distribution structure 20 mounted within the building below a ceiling 12 of a room to be lit. As shown in FIG. 1D, light rays 8a, 8b (depicting the outer and inner bounds of light captured by the primary reflector 10) incident on the primary reflector 10 are reflected and concentrated to the secondary reflector 60, which reflects a substantially collimated flux into the transmission conduit 130, shown in FIG. 1A. The concentrated light rays emerging from the transmission conduit 130 are incident on the light distribution structure 20 shown in FIG. 1A and are redirected laterally outward and upward onto the walls and ceiling of a room within the building. The ceiling and walls are preferably coated with a diffusely reflecting material of high reflectivity to aid in the diffusion of light throughout the room, but in certain desirable cases, this distribution method can be replaced with alternate luminaire designs more appropriate for task lighting (not shown).

The primary reflector 10 may be formed as a concave parabolic trough having a perimeter surrounding a reflective surface with a center. The primary reflector 10 may extend laterally and terminate at longitudinal tips 11, illustrated in FIG. 1D. The primary reflector 10 may have a transverse axis 75 perpendicular to a longitudinal axis 30 and an optical axis 35 perpendicular to the transverse and longitudinal axes, all three coinciding with the center 40 of a hole or aperture 14 in the center of the primary reflector. and the point 40 of intersection of the three axes is coincident with the surface of the primary reflector 10 (for the purpose of definition, hypothetically extended to fill in the central hole 14 shown in FIG. 1A). The primary reflector 10 has an optical axis 35 extending through the center point 40 of the longitudinal axis 30, perpendicular to both the longitudinal axis 30 and the transverse axis 75.

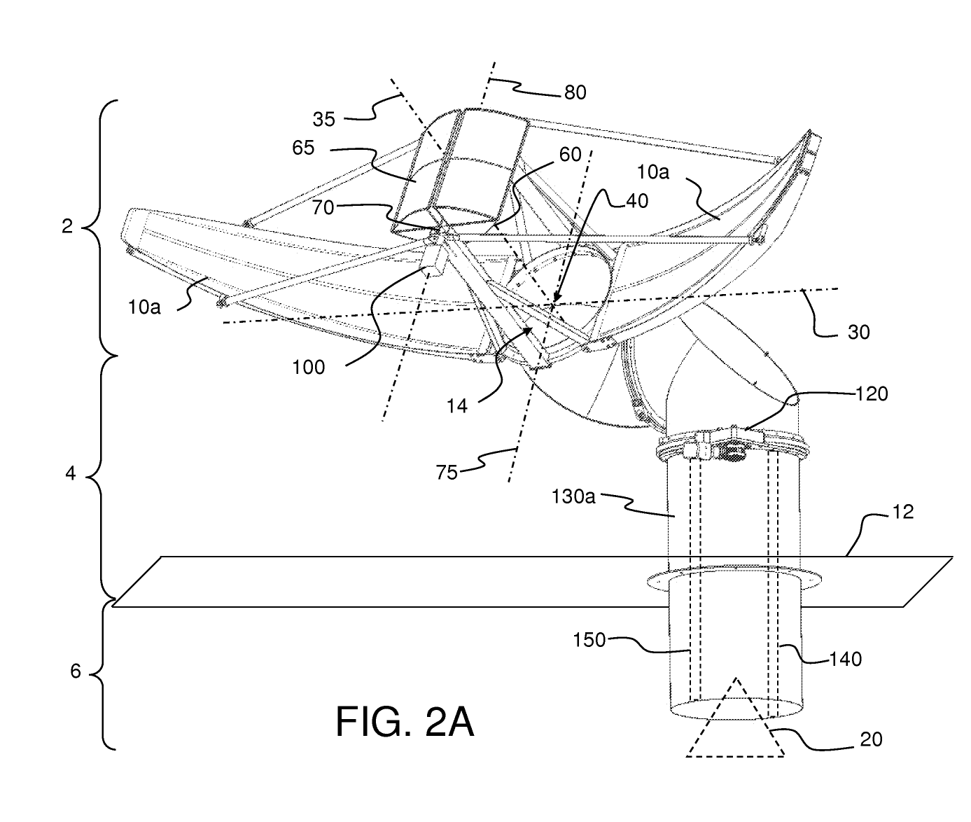

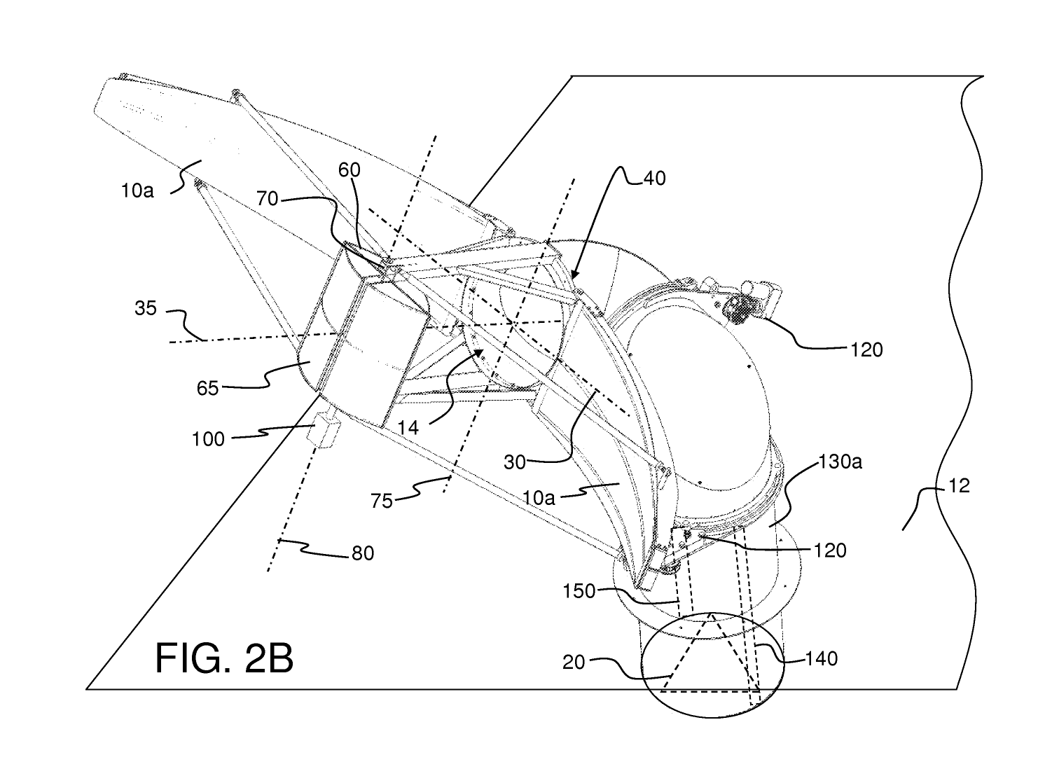

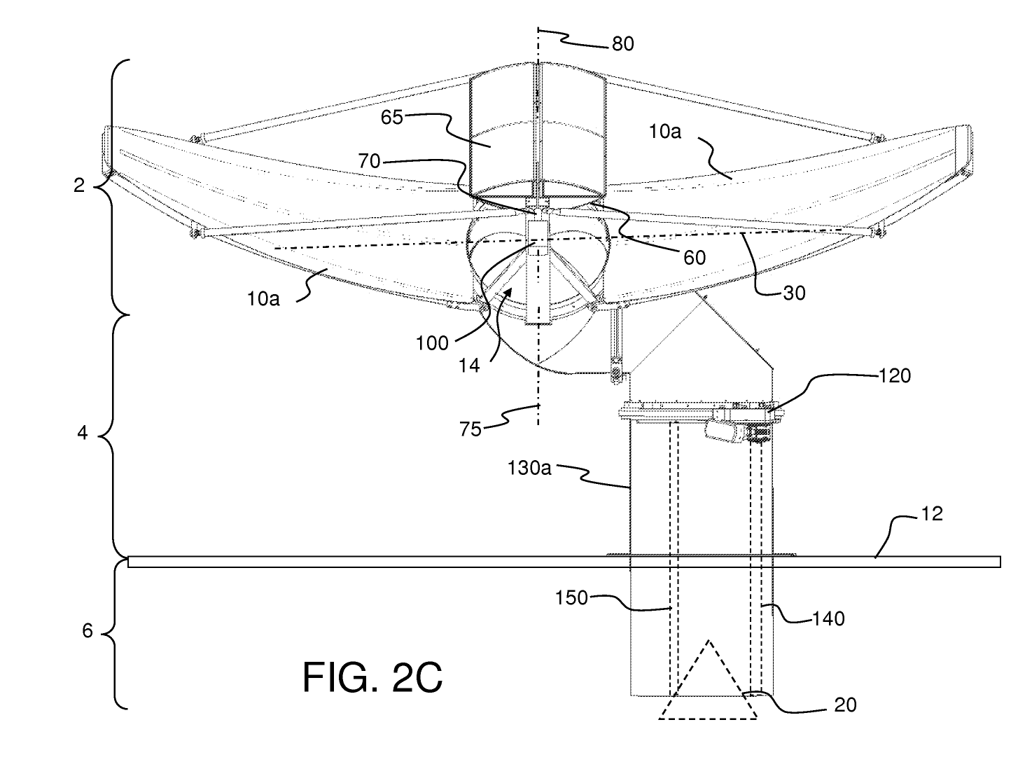

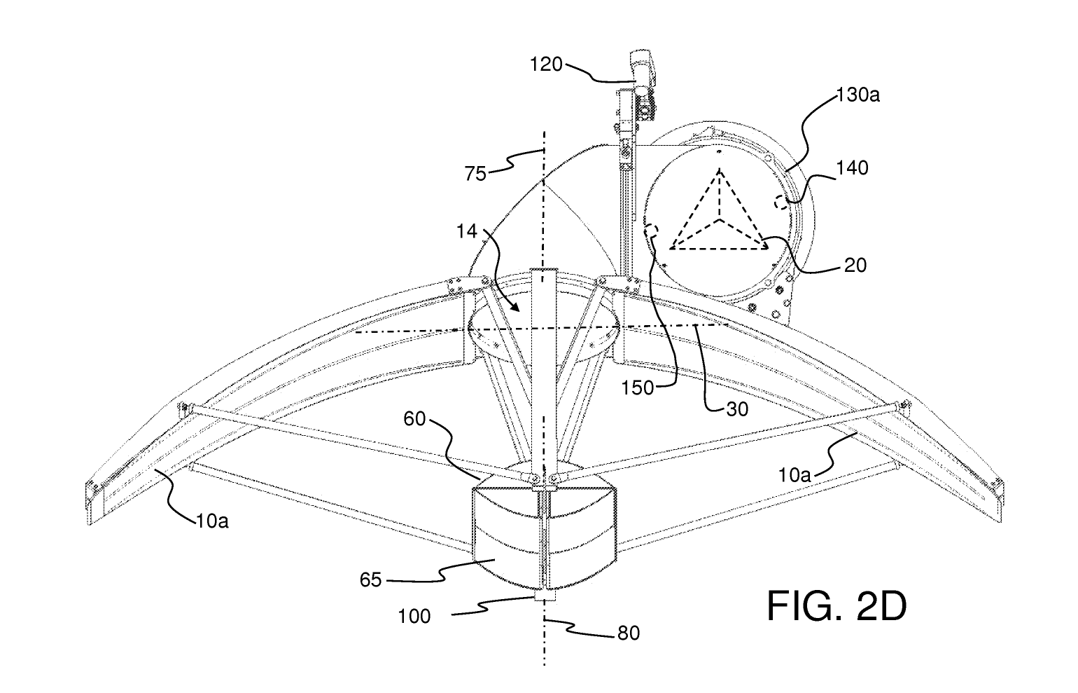

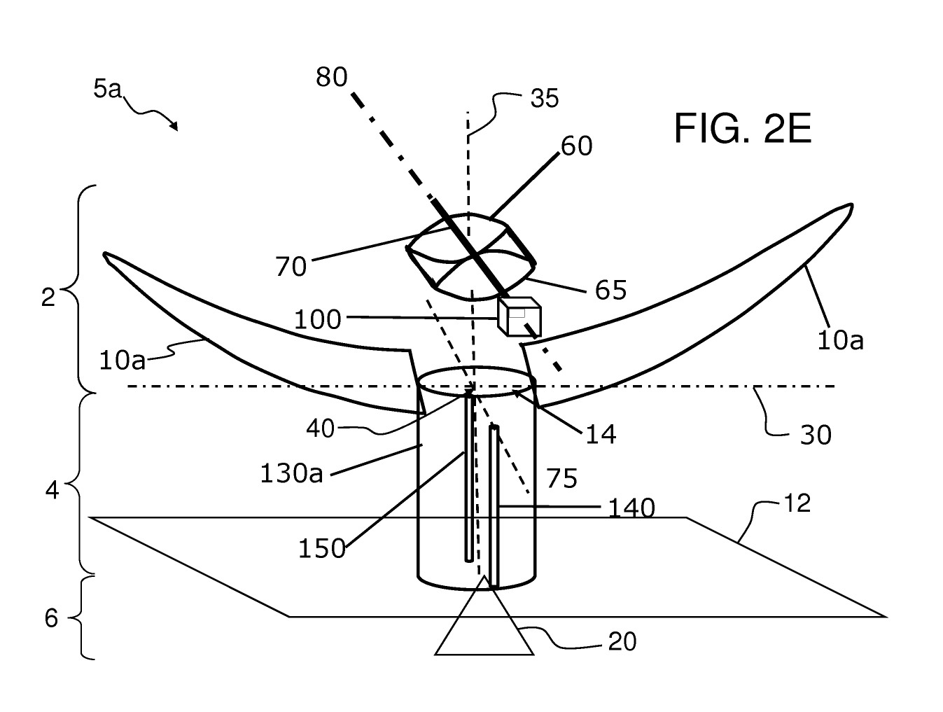

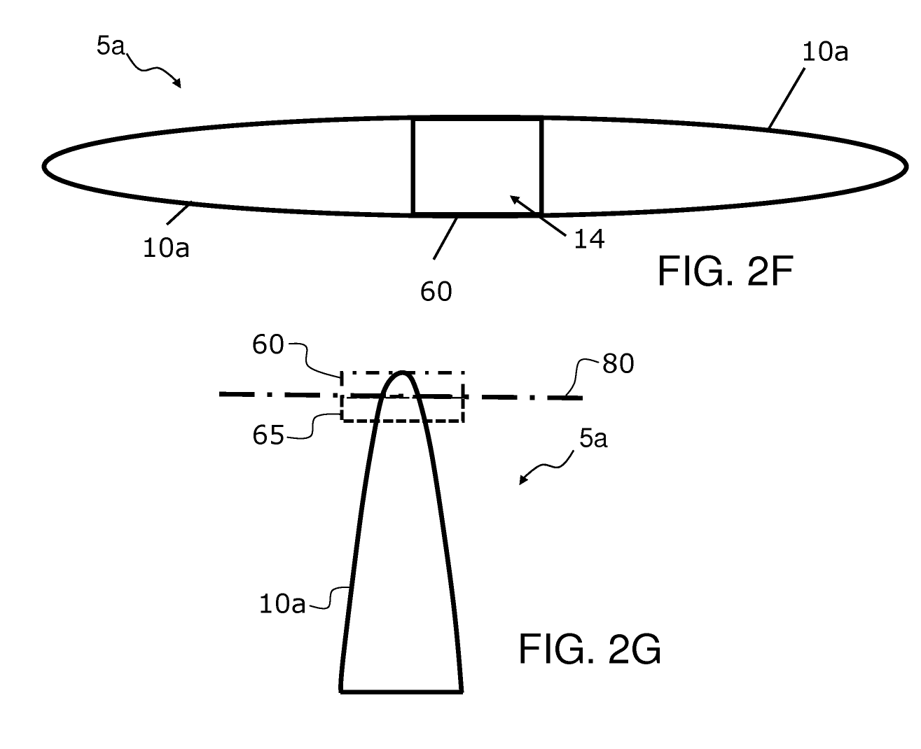

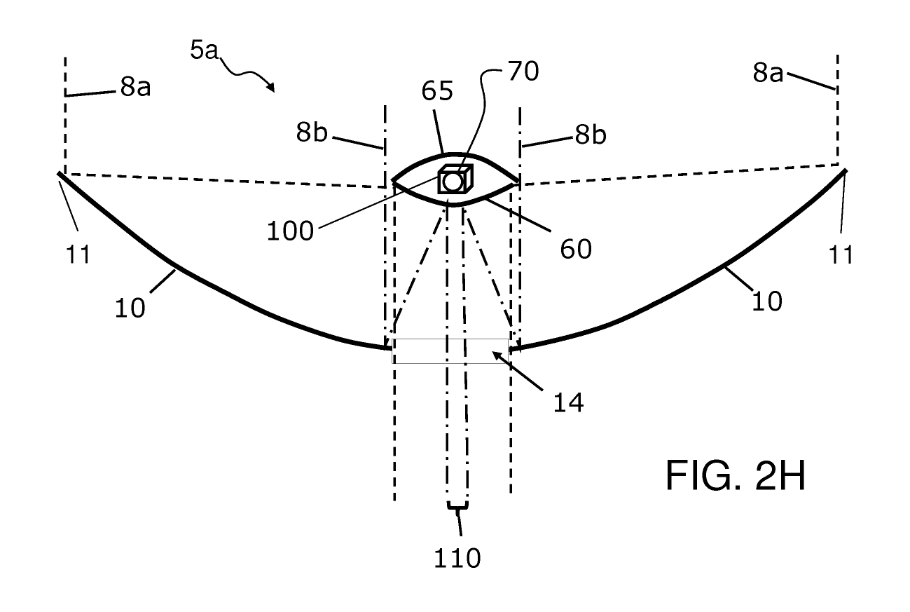

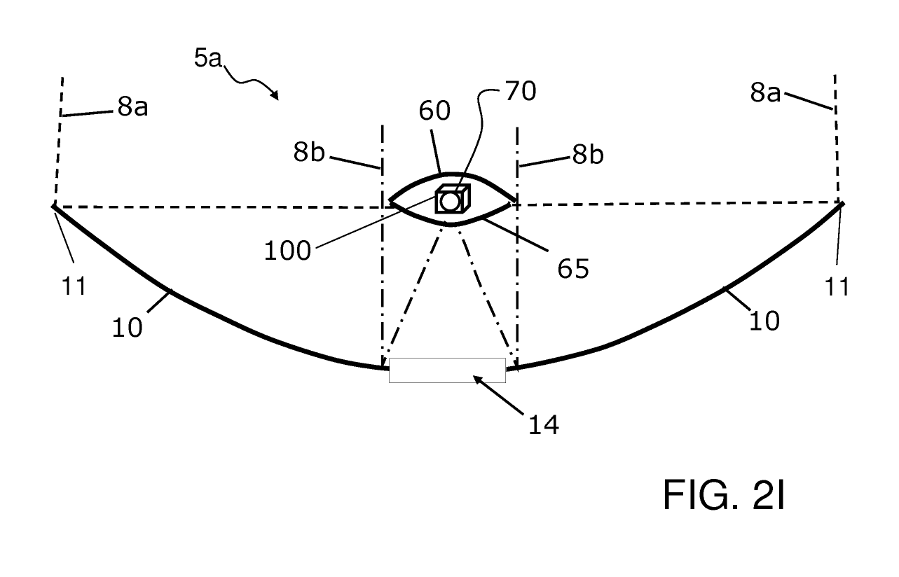

As shown in FIGS. 1A-2A, the primary reflector 10 may have a rectangular or other polygonal or curved profile or edge when considered as a projection of the perimeter onto a plane perpendicular to the optical axis 35. The primary reflector 10 has a parabolic shape in its longitudinal direction but has no curvature in the direction of the transverse axis 75. The primary reflector 10 may be configured with a hole 14 centered on the center point 40 through which a small portion of the quasi-collimated solar energy reflected from the secondary reflector 60 passes in order to enter the light transmission conduit 130. In an alternative embodiment, the primary reflector 10 may be formed of two separate lateral wings separated by a gap or span 14 centered on the center point 40 through which the solar energy reflected from the secondary reflector 60 passes in order to enter the light transmission conduit 130.

In one exemplary version of this configuration, the length of the secondary reflector 60 is approximately 23.2 in. and the length of the primary reflector 10, including the gap or hole, is approximately 155 in. The combination of the primary reflector 10 and the secondary reflector 60 in the daylighting system 5 results in a net solar energy concentration ratio, wherein the incident light is concentrated and focused by the reflectors. In one exemplary configuration, the front vertex of the secondary reflector 60 is approximately 32.5 in. from the plane of the gap or hole 14 in the primary reflector 10 and the focal point from of the primary reflector 10 is approximately 38 in. from the plane of the gap or hole 14 in the primary reflector 10, i.e., behind the vertex of the secondary reflector 60. In one exemplary implementation, the length of the secondary reflector 60 and the length of the primary reflector 10 may be chosen such that the net concentration ratio may be between 3 and 7. For proper collimation of the radiation reflected by the secondary reflector, the primary and secondary reflectors may be positioned in a confocal arrangement whereby the focal lines of the two reflectors are coincident and located above the surface of the secondary reflector 60 in FIG. 1D.

The primary reflector 10 and secondary reflector 60 may be mounted on an azimuthal drive mechanism 120 (see FIGS. 2A-2D), e.g., a carousel or “lazy Susan” bearing, attached to a mounting surface on the roof of a building or a motor drive system that rotates sections of the daylighting system with respect to each other and the mounting surface. The azimuthal drive mechanism rotates the reflectors such that the primary and secondary reflectors track the azimuth of the sun. Any of several conventional embodiments of motorized rotating tracks and wheel or bearing supports can be used, but it is desirable to select a system that minimizes friction torque and electrical energy needed to rotate the daylighting system. The azimuthal drive mechanism minimizes losses of solar flux by orienting the primary reflector 10 toward the azimuth of the sun while the geometric relationship between the primary reflector 10, the secondary reflector 60, and the light transmission conduit 130 remains constant.

The primary and secondary reflectors may alternatively be mounted on an altitude drive mechanism (not shown) having a horizontal axis of rotation bearing. The altitude drive mechanism may, in turn, be mounted on an azimuthal drive mechanism. This combination of altitude and azimuth axes in a two-axis tracking system further minimizes solar losses by keeping a Mersenne-like optical system with a trough-shaped concentrating reflector constantly aligned with the solar disk while at the same time constantly delivering the collimated concentrated beam of flux from the secondary reflector vertically downward into the structure below.

As shown in FIGS. 1A and 1C-1E, a curved PV array 65 may be mounted to the back side of a mount 70 supporting the secondary reflector 60. A drive mechanism 100 may be used to rotate the mount 70 into either of two positions, i.e., the secondary reflector 60 directed toward the aperture 14 or the PV array 65 directed toward the aperture 14. The axis of rotation 80 of the mount 70 holding the secondary reflector 60 and the PV array 65 in place is depicted as a dashed line in FIG. 1A. The axial mount 70 is depicted in FIG. 1A as a solid line. In one embodiment, the drive mechanism 100 may be a motor with a shaft output coupled with a pivot hinge on the mount 70. In another embodiment, the drive mechanism 100 may be a solenoid that translates between a first position and a second position. The drive mechanism 100 may be actuated by a control system (not shown) that selectively changes the position of the mount 70 depending upon the needs of the building. An exemplary control system may consist of a computational device, e.g., a microprocessor, an integrated circuit chip, or a computer, for determining the position of the sun in the sky for a particular latitude and longitude any time of the day (e.g., via a stored look-up table) and for converting this positional information into command or instructions sent electrically to the tracking motors. Such system may also include an electrical signal from a sensor measuring the strength of the direct solar beam output by the secondary reflector, thereby indicating when that strength might fall below a minimum value. A sensor for sensing the presence of persons in the illuminated space may be connected to the computational device, thereby indicating the need for daylight in the space or lack thereof. Such signals may be used to send commands or other information to switch between the secondary reflector 60 facing the primary reflector 10 and the PV array 65 facing the primary reflector 10.

For example, should a person enter the building and interior lighting is needed, the control system may cause drive mechanism 100 to rotate the mount 70 and orient the secondary reflector 60 toward the aperture 14 as shown in FIG. 1D to direct the concentrated light within the transmission conduit 130 for distribution and diffusion within the building. Alternatively, if no one is occupying the building and interior light is not needed, the control system may direct the drive mechanism 100 to orient the mount 70 such that the PV array 65 is directed toward the aperture 14 as shown in FIG. 1E to receive the concentrated light energy directed to it by the primary reflector 10 to generate electricity for operating the daylighting system 5, for storage, or otherwise. If the control system senses that there is inadequate solar radiation available, it may send commands to switch the secondary reflector support structure between its two different orientation states for the purpose of weather protection or other designed intent.

In still another embodiment, the drive mechanism 100 may be a solenoid rotating the mount 70 against the force of a spring or gravity to the orientation whereby the secondary reflector 60 is facing down toward the primary reflector 10, sending sunlight into the distribution system. In the event of power failure, the solenoid would cease to be energized and the mount 70 would rotate to orient the PV array 65 in the beam reflected from the primary reflector 10, and the power generated by the PV array 65 may be used to either charge batteries or energize emergency backup electric lighting inside the building, or it may be put other uses.

The PV array may be composed of PV cells designed to take advantage of the concentrating power of the primary reflector 10 without adverse impact to the PV cell array's short or long term performance. Concentrated PV is generally classified in low, medium, and high concentration ratios. Low concentration is generally defined as 1-10 times concentration, medium concentration is generally defined as 10-100 times concentration, and high concentration is generally defined as over 100 times concentration. Low and medium concentration PV are generally attainable with primary reflectors of the daylighting systems described herein. As noted above, in an exemplary configuration, the concentration ratio may be between 3 and 7. High concentration PV, although possible, is generally unrealistic given the modest the tracking accuracy required for most daylighting systems and desires to avoid the possible danger of very high concentration ratios.

In an alternate embodiment shown in FIGS. 2A-2I, the perimeter of the primary reflector 10a may be formed so that when the shape of the perimeter of the primary reflector 10 is projected onto a plane perpendicular to the optical axis 35, an ellipse with a semi-major axis in the longitudinal direction is formed. Due to the projected elliptical shape of the primary reflector 10a, the concentrated light may be in the form of a circular beam approaching the secondary reflector 60 and its reflection from the secondary reflector may be a quasi-collimated vertical beam relative to the drawing of FIG. 2E having an approximately circular cross sectional shape. The secondary reflector 60 and the PV array 65 may therefore have equal circular perimeters when projected onto a plane perpendicular to the optical axis 35. (Alternatively, they may have square projected perimeter shapes as depicted in FIG. 2E, e.g., to save on fabrication costs without compromising optical performance.) Therefore, the transmission conduit 130a may have a circular rather than rectangular cross section. In all other respects, the embodiment of FIGS. 2A-2I may be the same as the embodiment of FIGS. 1A-1E.

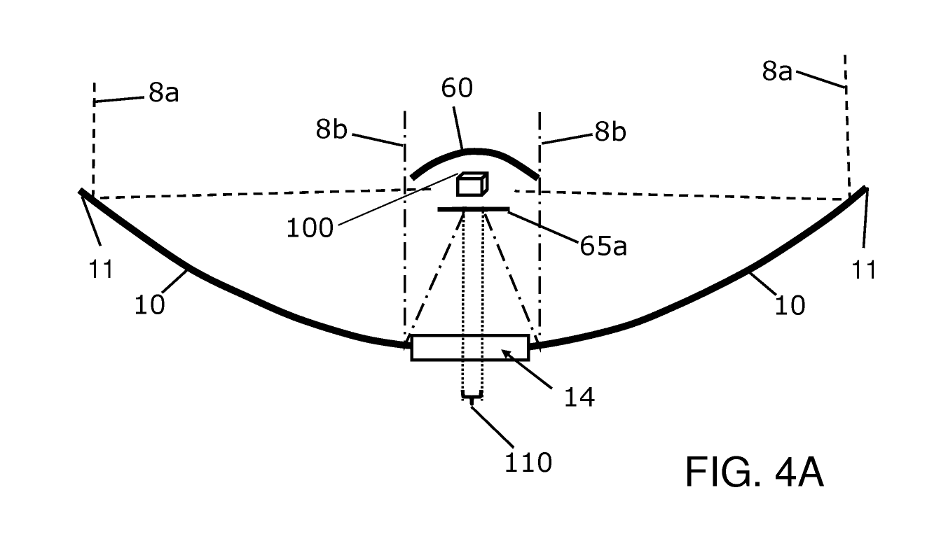

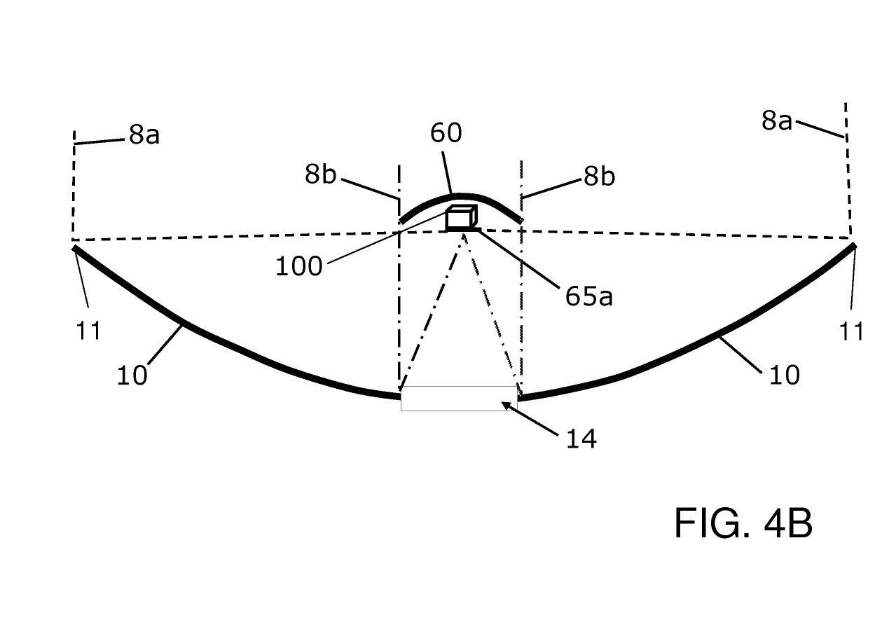

Alternatively, the PV array panel as shown in FIGS. 1A-2I may be a rectangular PV array for receiving concentrated solar radiation with a width equal to the width of the secondary reflector 60, but with a longitudinal length equal to or smaller than the longitudinal length of the secondary reflector 60 such that the PV array panel may be either flat or curved and mounted within the concave area on the back side of the secondary reflector 60 if desired. Such an implementation of the flat array is illustrated in FIG. 4A and is further described below with respect thereto.

In any of the implementations described herein, the daylighting system 5 may include a failsafe system to protect people and materials within the building from the effects of exposure to concentrated solar radiation in the event of a mechanical failure of the daylighting system 5. As part of the failsafe system, the transmission conduit 130 may be equipped with two or more circuit conductors 140, 150 about its perimeter. While one conductor may be sufficient, additional conductors may be desirable for redundancy. Upon a mechanical failure of a support mechanism mounting harvester portion 2 of the daylighting system 5 to a roof or other surface of a structure (e.g., due to high wind speed), one or more of the circuit conductors 140, 150 may sever under the strain between the harvester portion 2 and the transmission portion 4 and would certainly sever should the harvester portion 2 detach from the transmission portion 4. When one of the circuit conductors 140, 150 is severed, the control system may place the secondary reflector mount 70 in the failsafe position such that the PV array 65, rather than the secondary reflector 60, points toward the primary reflector 10. In this way, the concentrated solar energy is prevented from entering the building and may be put to beneficial use.

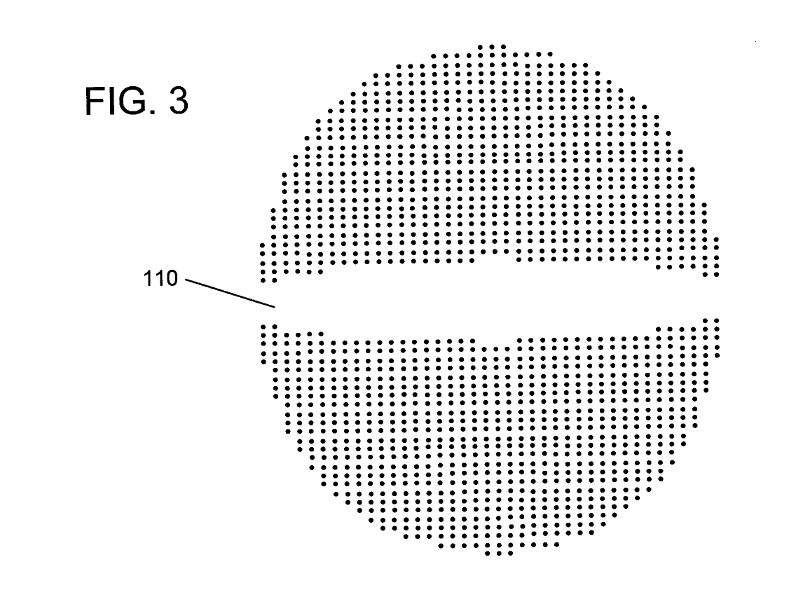

Note that due to the shadow of the secondary reflector 60 on the primary reflector 10, a hole, void, or lacuna 120 in FIG. 1D is caused in the concentrated light flux reflected from the secondary reflector 60 through the aperture 14 into the transmission conduit 130. In the case of a daylighting system 5 configured with a square projected perimeter secondary reflector 10, the lacuna 120 is rectangular in shape. The width of the lacuna in such a configuration approximately matches the projected width of the secondary reflector, but its longitudinal length is from 3 to 7 times shorter than that of the secondary reflector (due to the concentration produced by the primary reflector in the longitudinal direction only), and appears within the center of the rectangular cross section of flux passing into the transmission conduit. Alternately, in the case of a daylighting system 5a configured with an elliptical primary reflector 10a, the lacuna 110 is elliptical in shape and appears within the center of the circular cross section of flux passing into the transmission conduit as shown, for example, by the ray-traced spot diagram provided in FIG. 3.

FIG. 3 illustrates a ray position diagram across the circular beam reflected from the secondary reflector 60 when an elliptical perimeter primary reflector 10a is used together with a circular perimeter secondary reflector 60. The hole or lacuna 110 in the flux across the center of this beam results from the shadow of the secondary reflector on the primary reflector as well as the aperture 14 in or gap between the two halves of the primary reflector 10 needed to accommodate the transmission conduit 130. This reduction in flux concentration in the center of the collimated light can have a negative effect on the distribution and diffusion of the light in the interior of the building. U.S. Patent Application Publication No. 2010/0091396, which is hereby incorporated herein by reference in its entirety, discloses several methodologies to address this problem. In the context of the present disclosure, the lacuna may also cause variations in the flux density of incident light from the primary reflector 10 on the PV array due to the shadow of the mount 70/secondary reflector 60/PV array 65 on the primary reflector, which may have a negative effect on the efficiency of the PV array 65. For example, a lacuna may result in a lower concentration of light in the center of a PV array 65 and, therefore, a lower electrical conversion output than if the entire PV array 65 received a uniformly high flux concentration.

There are several possible methodologies to address the lacuna effect on the PV array and increase the uniformity of concentration of light incident on the PV array 65. FIGS. 4A-4B depict one possible scenario wherein the PV array 65 is flat and narrow rather than concave and is held on the mount 70 within the concave shape on the back side of the convex secondary reflector 60. As shown in FIG. 4A wherein the PV array 65a is mounted closer to the primary reflector 10 than in FIG. 4B, the lacuna 110 is still large. However, by instead placing the flat PV array 65a further from the primary reflector 10 and slightly beyond the focus of the primary reflector 10, a high flux concentration can be achieved and a smaller PV array can be used, thereby saving cost. The mount 70 for the PV array 65a may be adjustable to provide for positional tuning of the PV array 65a upon installation in the field or to accommodate PV arrays 65a of various sizes to achieve maximum flux on the PV array 65a. Some positions of the PV array 65a may reduce the size of the lacuna in the beam incident upon it, as suggested in FIG. 4B.

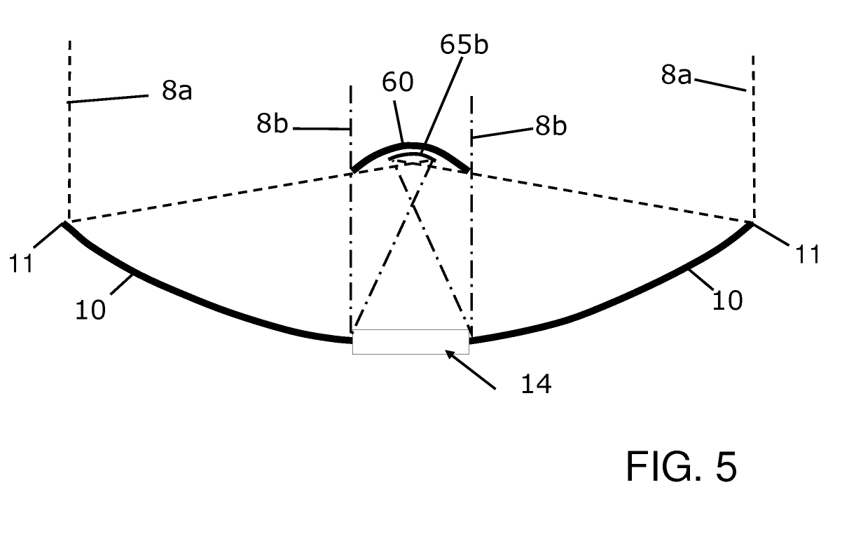

Another possible configuration for remedying the lacuna effect is shown in FIG. 5 in which the PV array 65b is formed as a concave curve to better capture the flux from the primary reflector 10 incident on it, more at normal incidence for increased conversion efficiency and thereby conforming more closely to the concave shape of the back of the secondary reflector 60. Again, the concave PV array 65b may be narrow in longitudinal length but match the full widths of the primary reflector 10 and secondary reflector 60 and may be located such that the focus of the primary reflector 10 is slightly in front of the surface of the PV array 65b at its lateral median, so that the flux diverging past the focal line will spread to properly fill the longitudinal length of the PV array 65b. The distance the PV array 65b is set from the focal line will determine the longitudinal length of the PV array 65b. The concentration ratio may also be set to maximize the cost/benefit/performance of the PV array 65b designed for use in concentrated sunlight.

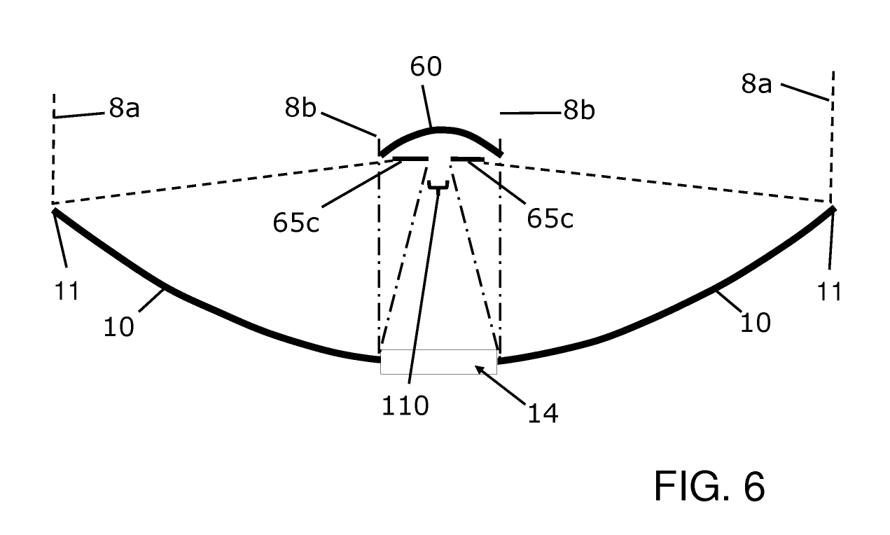

A further possible option for remediation of the lacuna effect is to split the PV array 65a in half, leaving a gap between the two halves equal to the longitudinal length of the lacuna 110 as shown in FIG. 6. In this exemplary implementation, the PV array 65c may be made of two narrow components separated by a gap equal to the longitudinal length of the lacuna 110 in the beam at that location, so that each of the components of the PV array 65c receive the concentrated flux on either side of the lacuna 110. Thus, this is also a cost saving design of higher overall efficiency because there is no underutilized PV material in the PV array 65c.

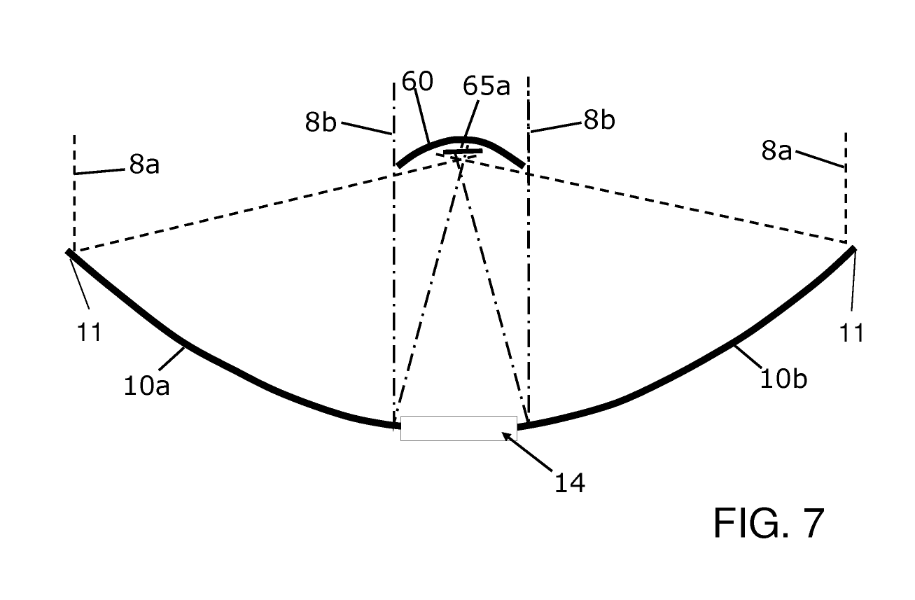

Yet another exemplary implementation of the daylighting system 5 designed to address the lacuna effect is depicted in FIG. 7. The way to understand the split mirror approach is to think of the primary as continuous, with no hole in it. The shadow of the secondary creates the lacuna in the beam reflected from the secondary that propagates along with that beam. To correct this problem, sections may be removed from the centers of the primary and secondary reflectors equal in longitudinal length to the longitudinal “length” of the lacuna. This lacuna length is the width of primary reflector 10 and secondary reflector 60, which are equivalent, divided by C, where C is the concentration ratio. C is approximately equal to the ratio of the longitudinal length of the primary reflector 10 (minus the hole in it) divided by the longitudinal length of the secondary reflector 60, assuming a rectangular primary reflector perimeter. It will be somewhat less for an elliptical primary reflector perimeter due to the smaller primary reflector area that intercepts solar radiation.

In this embodiment, the primary reflector 10 is truncated at each inner lateral end of the two halves 10a, 10b adjacent the aperture 14. A rectangular section may be removed from both sides of the primary reflector 10 across its plane of symmetry. Each rectangular section may have a width equal to half the “longitudinal length” of the lacuna. The “longitudinal length” is defined as the width of primary reflector divided by C, where C is the concentration ratio. The truncated halves of the primary reflector 10a, 10b are then rejoined at the edges of the aperture 14 along the plane of symmetry while maintaining the original angular orientation.

In order to correct the secondary reflector for the removal of a section of the primary reflector, a central section of the secondary reflector 60 is removed that is of the same width, left to right in FIG. 7, as the sections removed from the primary reflector 10 and the remaining halves of the secondary reflector 60 are then rejoined at the center, producing a compound reflector. By truncating the primary reflector 10 and the secondary reflector 60 in this manner, the effect of the lacuna is greatly minimized and a generally uniform flux concentration is received at the PV array 65a, which in this case is shown as a narrow, flat array similar to that of FIG. 4B, although other configurations are possible.

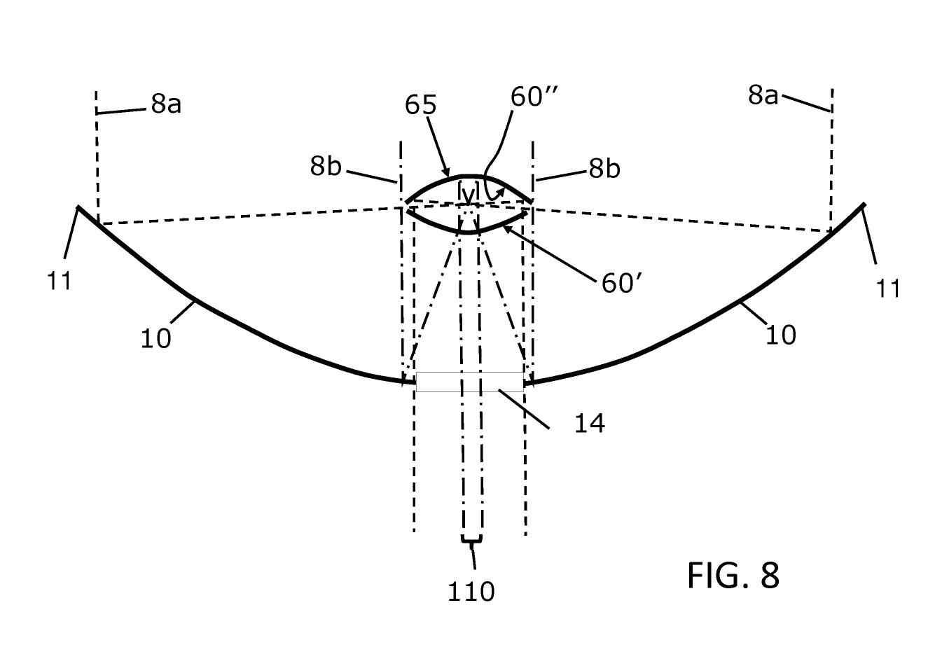

FIG. 8 illustrates conceptually a relationship between the optics of the primary reflector 10 and its focal line, showing that there are two ways to produce a collimated, reflected beam from a secondary reflector 60 placed first in front 60′ of the focal line of a primary reflector 10 and then behind that focal line 60″.

In the first case in which the secondary reflector 60′ is oriented as a convex parabolic surface positioned in front of the focal line, the secondary reflector 60′ intercepts the beam from the primary reflector 10 converging toward its focal line before it can reach the focus and reflects and collimates that beam. The reflected beam will have the same lateral width as the primary reflector 10 and secondary reflector 60′ and the longitudinal “length” (left to right on the drawing) will be whatever is set by the designed distance of the secondary reflector 60′ from the primary reflector 10. To create a square or circular beam reflected from the secondary reflector 60′ and passing through the hole 14 in the primary reflector 10, the longitudinal length of the secondary reflector 60′ is selected to match the lateral width of both reflectors.

In the second case in which the secondary reflector 60″ is positioned behind the focal line, a concave parabolic form secondary reflector 60″ can also collimate the incident beam, sending it down through the hole 14 in the primary reflector 10, in the same manner and with the same longitudinal and lateral dimensions. This implies that the secondary reflector 60″ may be concave and the PV array 65 may be a surface conforming to the convex opposing side of the secondary reflector 60″ (or vice versa). Thus, the concave, reflective side of a secondary reflector 60″ of this configuration will direct the collimated beam down through the hole 14 in the primary reflector 10 as desired and, when flipped over, the convex PV covered side 65 will collect the concentrated flux from the primary reflector 10 and convert it into electricity. This approach has the advantage that the axis of rotation will be through the focal line of the primary reflector 10. When the secondary reflector 60″ is in position, it is important that the rotation mechanism be outside the aperture of the secondary reflector 60″, so as not to shadow the latter. This is easily accomplished through the use of two bearings at the lateral ends of the axis of rotation attached to the lateral edges of the secondary reflector 60″/PV array 65 combination.

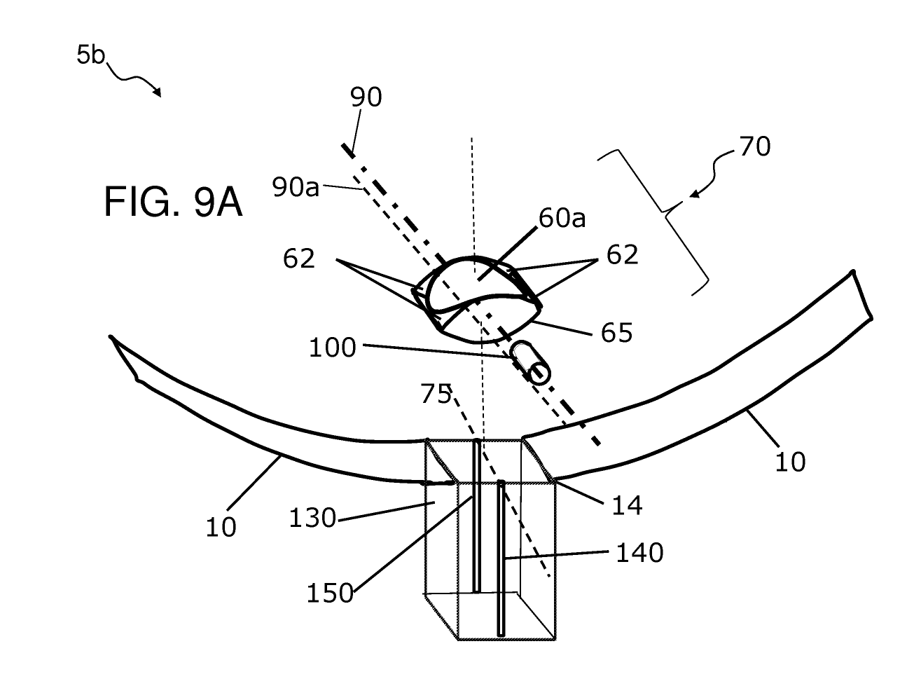

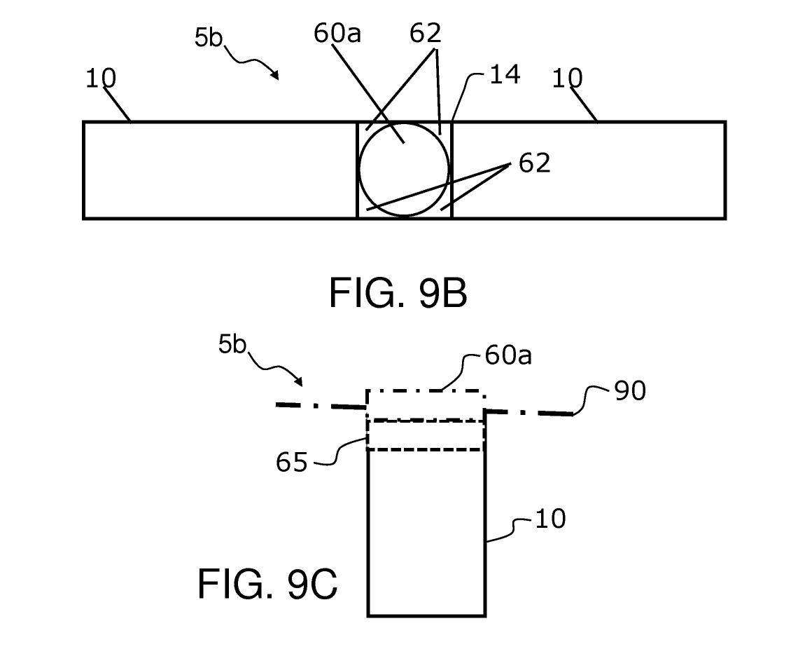

FIGS. 9A-9C illustrate a further implementation of a daylighting system 5b. The primary reflector 10 may have a perimeter profile which projects onto a plane perpendicular to the optical axis as a rectangle and which produces a reflected beam having a square perimeter. The concentrated beam reflected from the primary reflector 10 converges on a rectangular mount 70. In this implementation, the parabolic secondary reflector 60a may have a circular perimeter as shown in FIG. 9A. For daylighting purposes, a circular reflected beam is generally desired, so that only the central circular (in projection) portion of the convex secondary reflector 60a is specularly reflective. The remaining unreflective corners of the mount 70 may be filled with PV cells 62 so that the extra solar radiation not used for illumination can be harvested to generate a small amount of electrical energy, possibly to charge the batteries driving the tracking of the system 5b to follow the sun's movement.

A convex surface on the back of rectangular mount 70, opposite the side holding the secondary reflector 60a, may be completely filled with PV cells 65. Thus, when the secondary reflector 60a faces the primary reflector 10, concentrated sunlight reflected from it is directed through the aperture 14 in the primary reflector 10 while the small PV array in the corners generates electricity. When daylighting is not needed from the system 5b, the control system flips mount 70 through 180 degrees, so that unconcentrated solar radiation on these PV cells 62 in the corners can generate electricity to add to the electricity generated by the larger PV array 65 facing the primary reflector 10 and receiving concentrated solar radiation.

As mentioned, in this configuration, the back of the secondary mount 70 may hold a rectangular perimeter (in projection) PV array 65. When the mount 70 is rotated so that the secondary reflector 60a faces the primary reflector 10, the back side of the mount 70 with the rectangular PV array 65 faces the sun and can generate electricity from the unconcentrated light incident on it, while the solar cells 62 adjacent the secondary reflector 60a generate electricity from the concentrated reflection from the primary reflector 10. Thus, solar electricity can be generated both while the daylighting system 5b is delivering sunlight to the interior of the building and while it is not. This relatively modest electricity generation may be used to power tracking electronics and drive motors of the daylighting system 5, with any excess amount left over being used for battery storage or for other uses.

As in prior embodiments, conductors 140 and 150 form a closed electrical circuit. If this circuit is broken due to mechanical disruption following failure of the roof support, the lost electrical signal can cause a control system to rotate the secondary reflector 60a into a “safe” configuration with the PV array 65 facing the primary reflector 10, thereby preventing concentrated solar radiation from propagating through the conduit 130 into the building space below, as a failsafe provision.

FIGS. 9A-9C also depict one an implementation of the daylighting system 5b in which the default configuration of the daylighting system 5b is a “safe” configuration in which the concentrated light is normally directed to the PV array 65 rather than into the transmission conduit 130. In the embodiment of FIGS. 9A-9C, in the absence of a control signal indicating that interior lighting is needed, the PV array 65 will be automatically positioned in the path of the concentrated light and electricity will be generated from whatever sunlight is available. One embodiment for accomplishing this default positioning is through a spring-loaded or gravity-actuated mechanism that forces the secondary reflector mount 70 into the PV mode in the absence of electrical power forcing the secondary reflector 60a in place for sunlight harvesting or when an electrical signal calling for sunlight is not present.

An off-center axis of rotation 90 for the movement of the secondary reflector mount 70 is shown in FIGS. 9A and 9C that allows gravity to force the secondary mount into the safe position in the event of loss of power to the motor or solenoid that rotates or holds the secondary reflector 60a in a position facing the primary reflector 10. The axis 90 may also be angled and somewhat off-center from the center of mass of the frame 70 and secondary reflector 60a and PV array 65 mounted thereon. An electrically powered actuator holds the frame 70 on the off-center rotational axis in the configuration with the secondary reflector 60a facing the primary reflector 10 to deliver the collimated beam of illumination to the space below. However, should the electrical signals flowing through circuits 140 or 150 be interrupted due to mechanical failure, gravity alone would be sufficient to return the frame 70 to the orientation where the PV array 65 faces the primary reflector 10.

It should be noted that as the daylighting system 5b is designed to track the sun, the direction of gravity will shift. Further, in the event of failure of the tracking mechanism, the direction of gravity relative to the daylighting system 5b could be significantly different. As a result, the positioning and orientation of the rotational axis 90 relative to the secondary reflector 60a/PV array 65 assembly should be chosen carefully so that the failsafe intended operation will work regardless of the orientation of the daylighting system 5b at the time of failure. Alternatively, other mechanical biasing mechanisms (e.g., springs, counterweights, eccentric weighting, etc.) may be used to return the frame 70 to the orientation where the PV array 65 faces the primary reflector 10 as a failsafe configuration.

Thus, in normal operation, the secondary reflector 60a faces up and away from the primary reflector 10, so no concentrated solar beam can be sent into aperture 14. Upon receiving a command from the room below or other control system input that lighting is needed, the drive mechanism 100 rotates the mount 70 against the failsafe bias force to the position the secondary reflector 65 toward the aperture 14. Solar radiation is thereby reflected from the primary reflector 10 onto the secondary reflector 60a where the light is further reflected and collimated by the secondary reflector 60a and sent down through the transmission conduit 130 into the room below. If the electrical circuits 140 or 150 are broken, the power facing the secondary reflector toward the primary is lost and either gravity or spring loading, rotates the secondary reflector mount 70 so that the secondary reflector 60a is facing away from the primary reflector 10 in the fail safe condition.

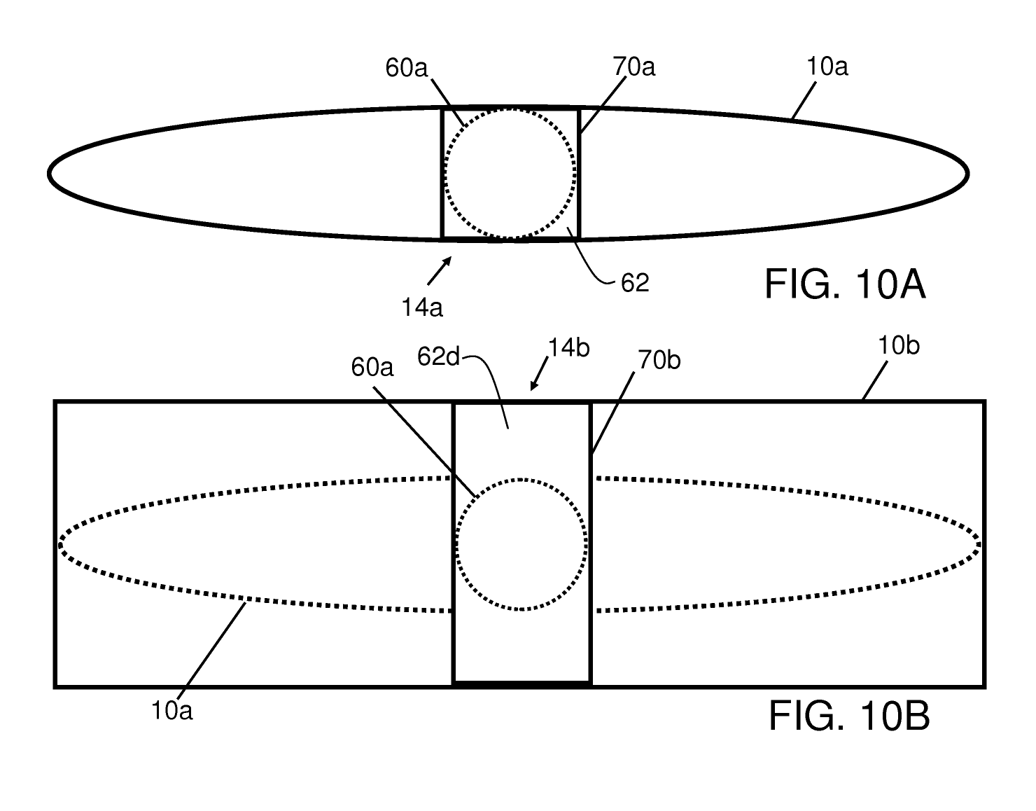

In another exemplary embodiment, a typical parabolic trough primary reflector 10a with an elliptical perimeter and a circular secondary reflector 60 is illustrated in FIG. 10A from a schematic top plan view. The support structure 70a for the secondary reflector 60 may be circular or square in shape. The area 62 surrounding the secondary reflector 60 may or may not be filled with PV cells, depending upon design choice. As shown in FIG. 10B, the primary reflector 10b is widened in the lateral direction to form a larger, rectangular perimeter shape to collect more solar flux. The support structure 70b is similarly widened to the same width as the primary reflector 10b. Since it is not desired to increase the diameter of the beam reflected from the secondary reflector 60 into transmission conduit, the surface of the secondary reflector 60 remains the same circular, parabolic trough-shape as in FIG. 10A and is not altered in size or shape.

The added area 14b surrounding the secondary reflector 60 on the secondary support structure 70b may be filled with PV cells 62a, as illustrated in FIG. 10B. The major consequence of this modification of the previous design is to greatly increase the concentrated solar flux incident on the PV cells 62a surrounding the secondary reflector 60 in the normal daylighting mode. The opposite side of the support structure 70b may also be completely filled with a solar cell array and receive non-concentrated direct beam and diffuse radiation from the sun, which is converted to electrical power to supplement the electricity being produced by the concentrated flux on the PV cells 62a on the other side, facing the primary reflector 10b. When sunlight is not needed and the support structure 70b is flipped 180 degrees, the back of the support structure 70b that is completely filled with PV cells receives the concentrated solar radiation from the expanded primary reflector 10b while the smaller area of PV cells 62a area on the other side surrounding the secondary reflector 60 receives unconcentrated solar and diffuse radiation. In both configurations, this embodiment may generate substantial quantities of solar electricity while producing solar lighting for building use when needed to displace electric lighting energy and provide good quality natural daylight.

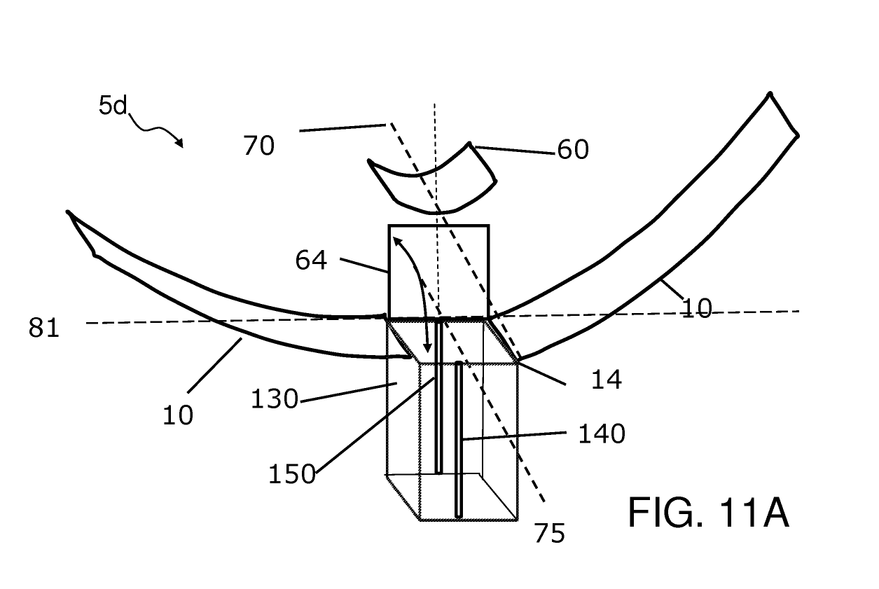

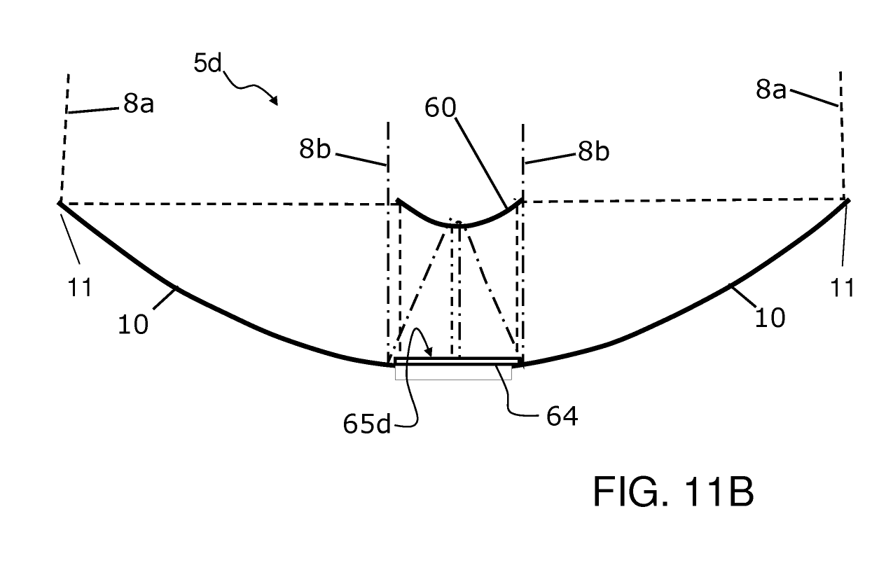

FIGS. 11A and 11B depict an alternative implementation of a concentrated PV collector for use with a solar daylighting system 5d. In this embodiment, the primary reflector 10 and the secondary reflector 60 are both trough-shaped, parabolic reflectors arranged in a typical Mersenne configuration as in FIGS. 1A-1E. Unlike the previous embodiments, however, the PV array 65d is mounted on the top surface of a pivoting cover 64 for the transmission conduit 130. It may be desirable to provide a cover 64 for the transmission conduit 130 for security, thermal, and/or sound insulation purposes. In this embodiment, the cover 64 is additionally employed to provide a mechanism for PV electrical generation when daylighting is not needed within the structure below the daylighting system 5d. In this implementation, the cover 64 is hinged along an edge of the transmission conduit 130 identified as axis 81. When the cover 64 is pivoted in a position covering the transmission conduit 130 as shown in FIG. 11B, the PV array 65d is placed directly in the path of the flux reflected from the secondary reflector 60 providing a substantially collimated beam of solar flux for generating electricity. The top surface 60 of the secondary reflector in the configuration of FIG. 11B may contain PV cells as well, thereby adding to the solar electricity generated by the PV array 65d on cover 64.

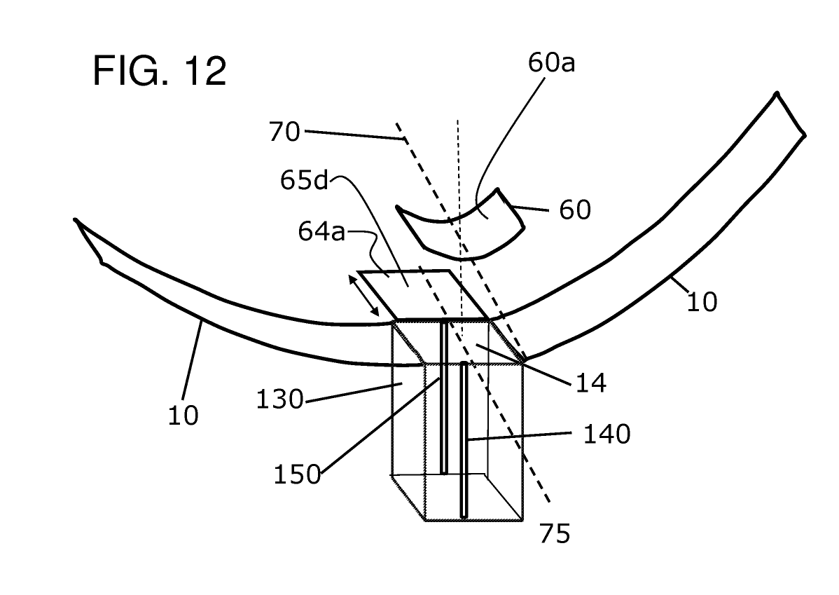

As shown in FIG. 12, in an alternative embodiment, the cover 64a may be mounted on a sliding track or otherwise move horizontally in a flat plane to cover or uncover the aperture 14 in the primary reflector 10 over the transmission conduit. The top surface of the cover 64a and the back of secondary reflector 60 may be covered by arrays of PV cells 65d and 60a. When the cover 64a is slid into a position covering the transmission conduit 130 and the aperture 14, the PV array 65d is placed directly in the path of the flux reflected from the secondary reflector 60 to provide a substantially collimated beam of solar flux for generating electricity.

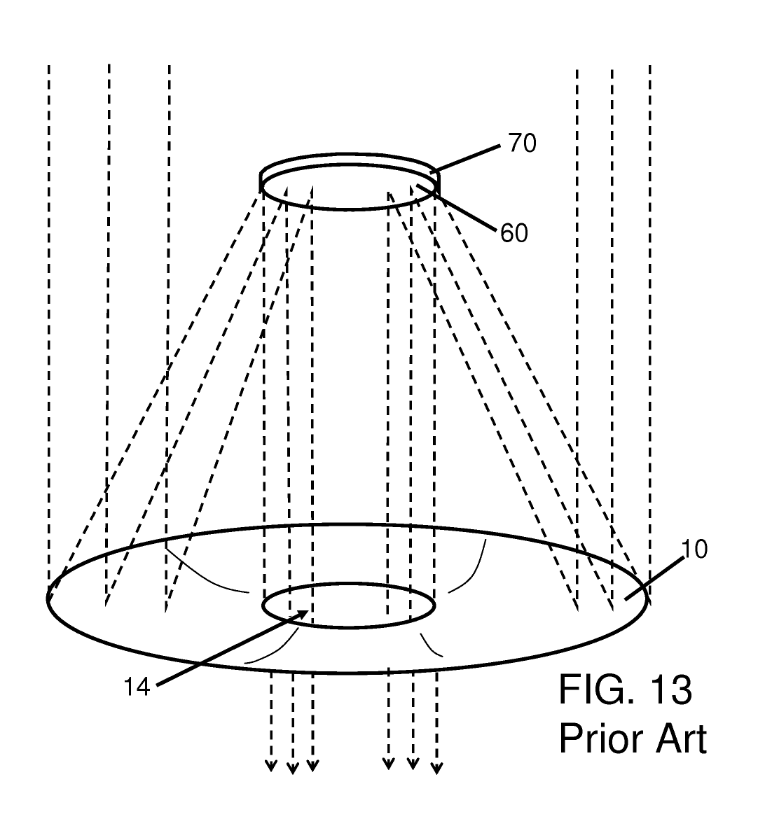

FIG. 13 depicts a typical dish-shaped Mersenne concentrating reflector system with a primary reflector 10 and a secondary reflector 60 fixed to a mount or support structure 70. Incident light is reflected from the primary reflector 10, concentrated on the secondary reflector 60, and further collimated and reflected through an aperture 14 in the primary reflector 10 to enter a transmission conduit for distribution in a structure below.

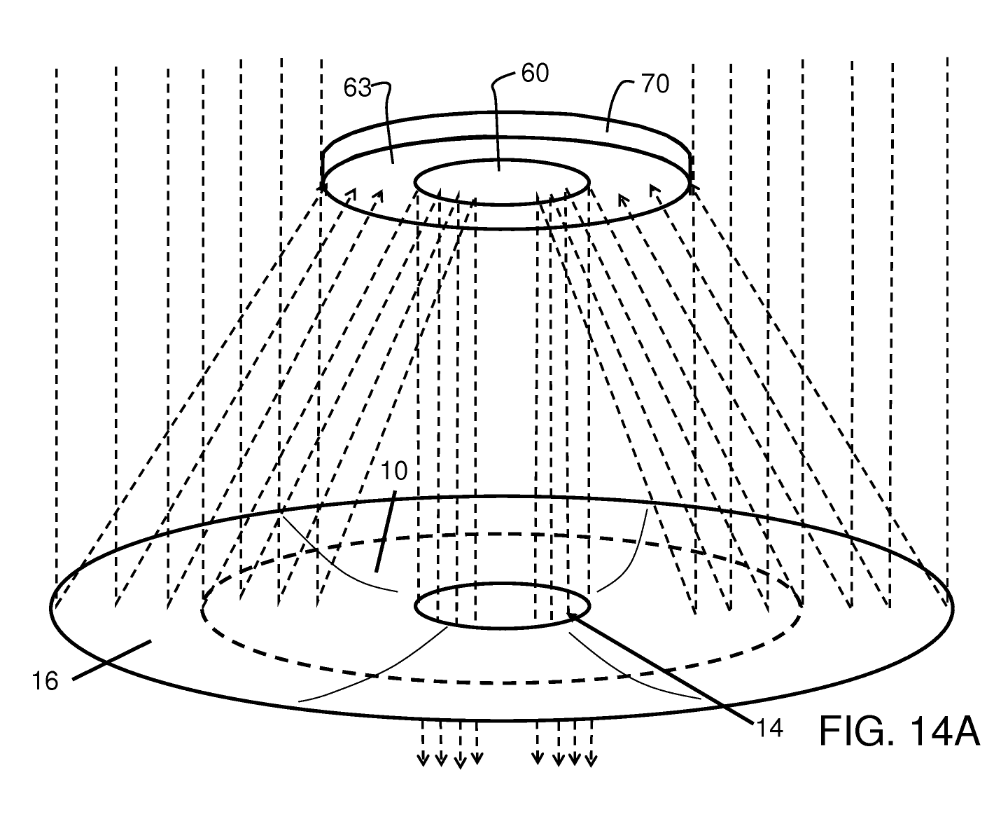

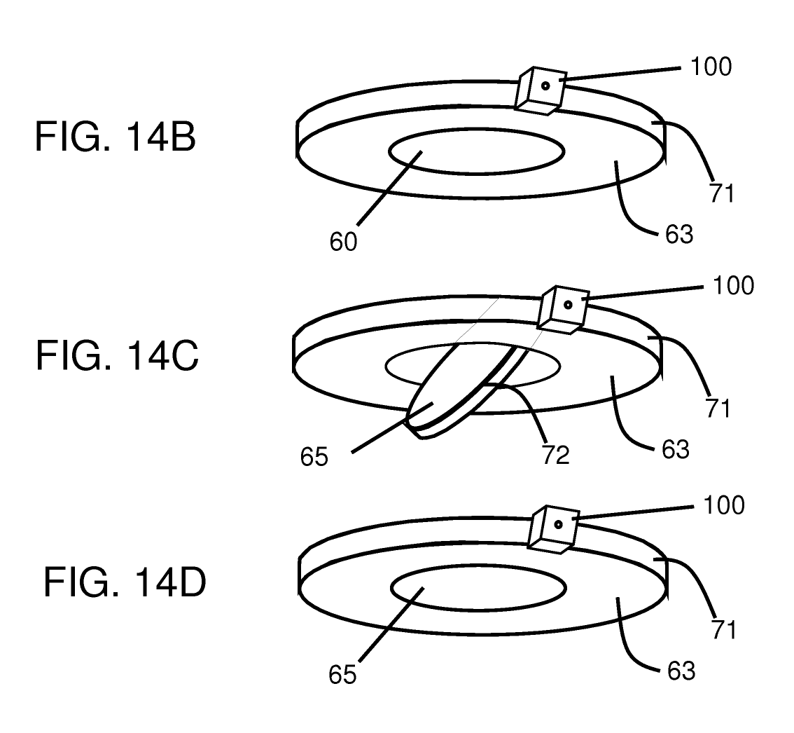

FIG. 14A depicts a modification to the typical design of the dish-shaped Mersenne concentrating reflector system of FIG. 13. The modified design of FIG. 14A provides a primary reflector 10 with an enlarged perimeter region 16 to collect more solar flux. This additional flux is unnecessary for the purpose of daylighting as reflection of light from the perimeter region 16 would be directed to an area outside the perimeter of the secondary reflector 60, which is sized to provide collimated light to an area the size of the aperture 14 in the primary reflector 10. However, in the embodiment of FIG. 14A, the diameter of the support structure 70 is enlarged beyond the diameter of the secondary reflector 60 and a PV cell array 63 is mounted on the extended perimeter region around the secondary reflector 60. In this configuration, the support structure 70 hosts both the secondary reflector 60 to transmit sunlight into a room to be illuminated and also the PV array 63 to collect and convert additional solar radiation into electricity for other uses.

As further shown in FIGS. 14B-14D, the support structure 70 may be formed in two parts with an inner mount 72 pivotally connected within an outer mount 71. The inner mount 72 supports the secondary reflector 60 while the outer mount supports the perimeter PV array 63. If no daylighting is needed in the structure below, or if the reflector system switches to safe mode, a drive system 100 (e.g., a motor or other device or configuration as described above) may rotate the inner mount 72 on an axis within an aperture in the outer mount 71 to direct the secondary reflector 60 away from the primary reflector. Additionally, a further PV array 65 may be mounted on the opposite side of the inner mount 72 from the secondary reflector 60 such that when the inner mount 72 is rotated, additional electrical generation capacity using the concentrated flux from primary reflector 10 is available. It should be noted that the top side of the outer mount 71 may also be covered by a PV array (not visible) such that electrical generation from unconcentrated incident sunlight on the top side of the mount 70 is available, both when the secondary reflector 60 is positioned upward and away from the primary reflector 10 and when the PV array 65 is oriented upward.

It should be noted that a PV array to selectively intercept the concentrated light from a primary and/or secondary reflector may be incorporated into other configurations of daylighting systems not explicitly shown herein. For example, a dish-shaped daylighting system having a bimodal circular dish as a primary reflector producing two point foci, side by side and a two-part paraboloidal convex dish as a secondary reflector, may incorporate a PV array on an opposing two-part paraboloidal convex dish that is rotated by a drive mechanism. Other implementations with other shapes and configurations of primary and secondary reflectors are also possible.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the present invention, and do not create limitations, particularly as to the position, orientation, or use of the invention. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other. The exemplary drawings are for purposes of illustration only and the dimensions, positions, order and relative sizes reflected in the drawings attached hereto may vary.

The above specification, examples and data provide a complete description of the structure and use of exemplary embodiments of the invention as defined in the claims. Although various embodiments of the claimed invention have been described above with a certain degree of particularity, or with reference to one or more individual embodiments, those skilled in the art could make numerous alterations to the disclosed embodiments without departing from the spirit or scope of the claimed invention. Other embodiments are therefore contemplated. It is intended that all matter contained in the above description and shown in the accompanying drawings shall be interpreted as illustrative only of particular embodiments and not limiting. Changes in detail or structure may be made without departing from the basic elements of the invention as defined in the following claims.

What is claimed is:

1. A solar daylighting apparatus comprising
a primary reflector positioned to receive and reflect incident sunlight;
a secondary reflector mounted at a position opposite the primary reflector to receive and reflect concentrated light reflected from the primary reflector;
a transmission conduit configured to receive concentrated light reflected from the secondary reflector and transmit the concentrated light to a distribution apparatus within a building;
a photovoltaic array movably mounted within the solar daylighting apparatus from a first position of noninterference with the reception of the concentrated light within the transmission conduit to a second position to receive the concentrated light reflected from either the primary reflector or the secondary reflector and thereby intercept the concentrated light and prevent reception of the concentrated light within the transmission conduit.

2. The apparatus of claim 1 further comprising a drive mechanism operably connected with the photovoltaic array to move the photovoltaic array between the first position and the second position.

3. The apparatus of claim 1 further comprising a biasing mechanism that biases the photovoltaic array in the second position.

4. The apparatus of claim 3 further comprising a drive mechanism operably connected with the photovoltaic array to move the photovoltaic array into the first position of noninterference thereby allowing reception of the concentrated light within the transmission conduit.

5. The apparatus of claim 4, wherein in an event of failure of power to the drive mechanism, the biasing mechanism biases the photovoltaic array in the second position.

6. The apparatus of claim 1, wherein the photovoltaic array is mounted to rotate about an axis between the first position and the second position.

7. The apparatus of claim 4, wherein the secondary reflector is mounted in a position opposite the photovoltaic array about the axis;
the secondary reflector is configured to be in the second position when the photovoltaic array is in the first position; and
the secondary reflector is configured to be in the first position when the photovoltaic array is in the second position.

8. The apparatus of claim 1, further comprising
a cover that rotates about the axis to cover and uncover the transmission conduit; and
wherein the photovoltaic array is mounted on the cover.

9. The apparatus of claim 1, further comprising
a cover that slides laterally in a plane to cover and uncover the transmission conduit; and
wherein the photovoltaic array is mounted on the cover.

10. The apparatus of claim 1, wherein the photovoltaic array is positioned with respect to a focal length of the concentrated light reflected from the primary reflector to minimize a lacuna in concentrated light reflected from the primary reflector resulting from shadowing of the primary reflector by the secondary reflector.

11. The apparatus of claim 10, wherein
the photovoltaic array has a concave surface with respect to incident concentrated light; and
the concave surface is positioned substantially beyond the focal length of the concentrated light.

12. The apparatus of claim 10, wherein
the photovoltaic array has a convex surface with respect to incident concentrated light; and
an apex of the concave surface substantially at the focal length of the concentrated light.

13. The apparatus of claim 10, wherein
the photovoltaic array is split into a first half and a second half;
the first half is positioned adjacent a first boundary of the lacuna; and
the second half is positioned adjacent a second boundary of the lacuna, whereby
the first half and the second half are on opposite sides of the lacuna.

14. The apparatus of claim 1 further comprising
a mounting platform that supports the secondary reflector, wherein
a width of the primary reflector perpendicular to both an optical axis and a longitudinal axis is larger than required to illuminate the secondary reflector for reflecting to the transmission conduit; and
a width of the mounting platform for the secondary reflector is equal to the width of the primary reflector in a direction parallel to the increased width of the primary reflector and defines an area extending beyond a perimeter of the secondary reflector; and
one or more photovoltaic solar cells mounted on the area of the mounting platform beyond the perimeter of the secondary reflector, wherein
the photovoltaic solar cells receive concentrated solar flux reflected from the larger than required width of the primary reflector beyond flux needed for illumination of the secondary reflector.

15. A solar daylighting apparatus comprising
a primary solar collector that concentrates incident light by reflection;
a secondary solar collector that receives concentrated light from the primary solar collector and that shifts from being a reflective concentrator to being a radiant energy collector.

16. A method for configuring a solar daylighting system having a photovoltaic array movably mounted within the solar daylighting system from a first position of noninterference with reception of concentrated light within a transmission conduit to a second position to receive the concentrated light reflected from either a primary reflector or a secondary reflector and thereby intercept the concentrated light and prevent reception of the concentrated light within the transmission conduit, the method comprising
identifying a lacuna in the concentrated light reflected from the primary reflector resulting from shadowing of the primary reflector by the secondary reflector; and
adjusting a configuration of the photovoltaic array with respect to a focal length of the concentrated light reflected from the primary reflector to minimize the lacuna.

17. The method of claim 16 wherein the adjusting operation further comprises
forming the photovoltaic array to have a concave surface with respect to incident concentrated light; and
positioning the concave surface substantially beyond the focal length of the concentrated light.

18. The method of claim 16 wherein the adjusting operation further comprises
forming the photovoltaic array to have a convex surface with respect to incident concentrated light; and
positioning an apex of the concave surface substantially at the focal length of the concentrated light.

19. The method of claim 16 wherein the adjusting operation further comprises
splitting the photovoltaic array into a first half and a second half;
positioning the first half adjacent a first boundary of the lacuna; and
positioning the second half adjacent a second boundary of the lacuna, whereby the first half and the second half are on opposite sides of the lacuna.

20. A method for increasing collection of photovoltaic energy in a solar daylighting system having a primary reflector, a secondary reflector, and a transmission conduit, the method comprising
increasing a width of the primary reflector perpendicular to both an optical axis and a longitudinal axis;
increasing a width of a mounting platform for the secondary reflector an amount equal to the increased width of the primary reflector and in a direction parallel to the increased width of the primary reflector;
populating an area of the mounting platform around the secondary reflector corresponding to the increased width with photovoltaic solar cells wherein the photovoltaic solar cells receive concentrated solar flux reflected from the increased width of the primary reflector beyond flux needed for illumination of the secondary reflector.
